(19) United States
(12) Patent Application Publication
(10) Pub. No.: US 2024/0145588 A1
(43) Pub. Date: May 2, 2024

(54) VERTICAL POWER SEMICONDUCTOR DEVICE INCLUDING A SILICON CARBIDE (SIC) SEMICONDUCTOR BODY

(71) Applicant: Infineon Technologies AG, Neubiberg (DE)

(72) Inventors: Thomas Ralf SIEMIENIEC, Villach (AT); Hans-Joachim Schulze, Taufkirchen (DE); Werner Schustereder, Villach (AT)

(21) Appl. No.: 18/382,816

(22) Filed: Oct. 23, 2023

(30) Foreign Application Priority Data
Oct. 27, 2022 (DE) 102022128515.4

(51) Int. Cl. H01L 29/78; H01L 29/06; H01L 29/16; H01L 29/66

(52) U.S. Cl. CPC H01L 29/7813; H01L 29/0696; H01L 29/1608; H01L 29/66734

(57) ABSTRACT

A vertical power semiconductor device includes a silicon carbide (SiC) semiconductor body having a first surface and a second surface opposite to each other along a vertical direction. The SiC semiconductor body includes at least one SiC semiconductor layer on a SiC semiconductor substrate. A pn junction is formed in the at least one SiC semiconductor layer. A first load electrode is arranged over the first surface. The vertical power semiconductor device further includes a plurality of first trenches extending into the SiC semiconductor substrate from the second surface. A second load electrode is arranged over the second surface. The second load electrode is electrically connected to the SiC semiconductor substrate via one or more sidewalls of the plurality of first trenches.

### RELATED APPLICATION

This application claims priority to German Patent Application No. 102022128515.4, filed on Oct. 27, 2022, entitled “VERTICAL POWER SEMICONDUCTOR DEVICE INCLUDING A SIC SEMICONDUCTOR BODY”, which is incorporated by reference herein in its entirety.

### TECHNICAL FIELD

The present disclosure is related to a vertical power semiconductor device, in particular to a vertical power semiconductor device including a silicon carbide (SiC) semiconductor body and to a method for manufacturing a vertical power semiconductor device.

### BACKGROUND

Technology development of new generations of vertical power semiconductor devices, such as, for example, SiC power semiconductor transistors such as metal oxide semiconductor field effect transistors (MOSFETs), or junction field effect transistors (JFETs), or SiC power semiconductor diodes, or SiC power semiconductor thyristors, aims at improving electric device characteristics and reducing costs by shrinking device geometries. Although costs may be reduced by shrinking device geometries, a variety of tradeoffs and challenges have to be met when increasing device functionalities per unit area. For example, a trade-off between area specific on-state resistance, Rₒₙ×A, and voltage blocking capability requires design optimization.

Thus, there is a need for an improved vertical power semiconductor device.

### SUMMARY

An example of the present disclosure relates to a vertical power semiconductor device. The vertical power semiconductor device includes a SiC semiconductor body having a first surface and a second surface opposite to each other along a vertical direction. The SiC semiconductor body includes at least one SiC semiconductor layer on a SiC semiconductor substrate. The vertical power semiconductor device further includes a pn junction in the at least one SiC semiconductor layer. The vertical power semiconductor device further includes a first load electrode over the first surface. The vertical power semiconductor device further includes a plurality of first trenches extending into the SiC semiconductor substrate from the second surface. The vertical power semiconductor device further includes a second load electrode over the second surface. The second load electrode may be electrically connected to the SiC semiconductor substrate via at least sidewalls of the plurality of first trenches. A ratio between a minimum lateral extent of the plurality of first trenches at the second surface and a depth of the plurality of first trenches from the second surface ranges from 0.5 to 5.

Another example of the present disclosure relates to another vertical power semiconductor device. The vertical power semiconductor device includes a SiC semiconductor body having a first surface and a second surface opposite to each other along a vertical direction. The SiC semiconductor body includes at least one SiC semiconductor layer on a SiC semiconductor substrate. The vertical power semiconductor device further includes a pn junction in the at least one SiC semiconductor layer. The vertical power semiconductor device further includes a first load electrode over the first surface. The vertical power semiconductor device further includes a plurality of first trenches extending into the SiC semiconductor substrate from the second surface. The vertical power semiconductor device further includes a second load electrode over the second surface. The second load electrode may be electrically connected to the SiC semiconductor substrate via at least sidewalls of the plurality of first trenches. A ratio between a depth of the plurality of first trenches and a thickness of the SiC semiconductor substrate ranges from 30% to 90%.

An example of the present disclosure relates to a method for manufacturing a vertical power semiconductor device. The method includes providing a SiC semiconductor body having a first surface and a second surface opposite to each other along a vertical direction. The SiC semiconductor body includes at least one SiC semiconductor layer on a SiC semiconductor substrate. The method further includes forming a pn junction in the at least one SiC semiconductor layer. The method further includes forming a first load electrode over the first surface. The method further includes forming a plurality of first trenches extending into the SiC semiconductor substrate from the second surface. The method further includes forming a second load electrode over the second surface. The second load electrode may be electrically connected to the SiC semiconductor substrate via at least sidewalls of the plurality of first trenches. A ratio between a minimum lateral extent of the plurality of first trenches at the second surface and a depth of the plurality of first trenches from the second surface ranges from 0.5 to 5.

Another example of the present disclosure relates to another method for manufacturing a vertical power semiconductor device. The method includes providing a SiC semiconductor body having a first surface and a second surface opposite to each other along a vertical direction. The SiC semiconductor body includes at least one SiC semiconductor layer on a SiC semiconductor substrate. The method further includes forming a pn junction in the at least one SiC semiconductor layer. The method further includes forming a first load electrode over the first surface. The method further includes forming a plurality of first trenches extending into the SiC semiconductor substrate from the second surface. The method further includes forming a second load electrode over the second surface. The second load electrode may be electrically connected to the SiC semiconductor substrate via at least sidewalls of the plurality of first trenches. A ratio between a depth of the plurality of first trenches and a thickness of the SiC semiconductor substrate ranges from 30% to 90%.

Those skilled in the art will recognize additional features and advantages upon reading the following detailed description, and upon viewing the accompanying drawings.

### BRIEF DESCRIPTION OF THE DRAWINGS

The accompanying drawings are included to provide a further understanding of the embodiments and are incorporated in and constitute a part of this specification. The drawings illustrate examples of vertical power semiconductor devices and together with the description serve to explain principles of the examples. Further examples are described in the following detailed description and the claims.

FIGS. 1 and 2 are partial cross-sectional views for illustrating exemplary vertical power semiconductor devices.

FIGS. 3A to 3H are partial cross-sectional views for illustrating a method of manufacturing vertical power semiconductor devices.

FIGS. 4A and 4B are partial cross-sectional views for illustrating exemplary vertical power semiconductor devices.

### DETAILED DESCRIPTION

In the following detailed description, reference is made to the accompanying drawings, which form a part hereof and in which are shown by way of illustrations specific examples of vertical power semiconductor devices. It is to be understood that other examples may be utilized and structural or logical changes may be made without departing from the scope of the present disclosure. For example, features illustrated or described for one example can be used in conjunction with other examples to yield yet a further example. It is intended that the present disclosure includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The term “electrically connected” may describe a permanent low-resistive connection between electrically connected elements, for example a direct contact between the concerned elements or a low-resistive connection via a metal and/or heavily doped semiconductor material. The term “electrically coupled” may include that one or more intervening element(s) adapted for signal and/or power transmission may be connected between the electrically coupled elements, for example, elements that are controllable to temporarily provide a low-resistive connection in a first state and a high-resistive electric decoupling in a second state. An ohmic contact may be a non-rectifying electrical junction.

Ranges given for physical dimensions include the boundary values. For example, a range for a parameter y from a to b reads as a≤y≤b. The same holds for ranges with one boundary value like “at most” and “at least”.

The terms “on” and “over” are not to be construed as meaning only “directly on” and “directly over”. Rather, if one element is positioned “on” or “over” another element (e.g., a layer is “on” or “over” another layer or “on” or “over” a substrate), a further component (e.g., a further layer) may be positioned between the two elements (e.g., a further layer may be positioned between a layer and a substrate if the layer is “on” or “over” said substrate).

An example of the present disclosure relates to a vertical power semiconductor device. The vertical power semiconductor device includes a SiC semiconductor body having a first surface and a second surface opposite to each other along a vertical direction. The SiC semiconductor body may include at least one SiC semiconductor layer on a SiC semiconductor substrate. The vertical power semiconductor device may include a pn junction in the at least one SiC semiconductor layer. The vertical power semiconductor device may further include a first load electrode over the first surface. The vertical power semiconductor device may further include a plurality of first trenches extending into the SiC semiconductor substrate from the second surface. The vertical power semiconductor device may further include a second load electrode over the second surface. The second load electrode may be electrically connected to the SiC semiconductor substrate via at least sidewalls of the plurality of first trenches. A ratio between a minimum lateral extent of the plurality of first trenches at the second surface and a depth of the plurality of first trenches from the second surface may range from 0.5 to 5.

The vertical power semiconductor device may be part of an integrated circuit or may be a discrete semiconductor device or a semiconductor module, for example. The vertical power semiconductor device may be or a may include a field effect transistor (FET), for example a junction field effect transistor (JFET) or an insulated gate field effect transistor (IGFET) such as a metal oxide semiconductor field effect transistor (MOSFET), or may be or a may include a power semiconductor diode, or may be or a may include a power semiconductor insulated gate bipolar transistor (IGBT), or may be or a may include a power semiconductor thyristor. The vertical power semiconductor device may have a load current flow between the first surface and the second surface opposite to the first surface. The vertical power semiconductor device may be configured to conduct currents of more than 1 A, or more than 10 A, or more than 30 A, or more than 50 A, or more than 75 A, or even more than 100 A, and may be further configured to block voltages between load electrodes, such as, for example, between the drain and source of a power MOSFET, or between cathode and anode of a power diode or power thyristor, or between collector and emitter of a power IGBT, in the range of several hundreds of up to several thousands of volts, such as, for example, 400 V, 650V, 1.2 kV, 1.7 kV, 3.3 kV, 4.5 kV, 5.5 kV, 6 kV, 6.5 kV, and/or 10 kV. The blocking voltage may correspond to a voltage class specified in a datasheet of the power semiconductor device, for example.

The vertical power semiconductor device may be based on a semiconductor substrate from a crystalline SiC material. For example, the semiconductor material may be 2H—SiC (SiC of the 2H polytype), 6H—SIC, 3C—SiC or 15R—SiC. According to an example, the semiconductor material is silicon carbide of the 4H polytype (4H—SiC). The semiconductor body may have one, two, or even more than two SiC layers, such as, for example, epitaxially grown SiC layers, thereon.

The first surface may be a front surface or a top surface of the semiconductor body, and the second surface may be a back surface or a rear surface of the semiconductor body, for example. The semiconductor body may be attached to a lead frame via the second surface, for example. Over the first surface of the semiconductor body, bond pads may be arranged and bond wires may be bonded on the bond pads, for example.

For realizing a desired current carrying capacity, the vertical power semiconductor device may be designed by a plurality of parallel-connected device cells, such as, for example, transistor cells, or diode cells, or thyristor cells, or IGBT cells. The parallel-connected device cells may, for example, be device cells formed in the shape of a strip or a strip segment. The device cells can also have any other shape, such as, for example, circular, elliptical, and/or polygonal such as hexagonal or octahedral. The device cells may be arranged in the active cell area of the semiconductor body. The active cell area may be an active area where a source region of the MOSFET or JFET (or anode region of the diode/thyristor or emitter region of the IGBT) at the first surface and a drain region of the MOSFET or JFET (or cathode region of the diode/thyristor or collector region of the IGBT) are arranged opposite to one another along the vertical direction. In the active cell area, a load current may enter or exit the semiconductor body, such as, for example, via contact plugs on the first surface of the semiconductor body. For example, the active cell area may be defined by an area where source contact plugs (or anode contact plugs or emitter contact plugs) are placed over the first surface.

The vertical power semiconductor device may further include an edge termination area. The edge termination area may include a termination structure. In a blocking mode or in a reverse biased mode of the vertical power semiconductor device, the blocking voltage between the active cell area and a field-free region may laterally drop across the termination structure in the edge termination area. The termination structure may have a higher or a slightly lower voltage blocking capability than the active cell area. The termination structure may include a junction termination extension (JTE) with or without a variation of lateral doping (VLD), one or more laterally separated guard rings, or any combination thereof, for example.

For example, the pn junction in the at least one SiC semiconductor layer may be a pn junction formed between the p-doped body region and an n-doped drift region of a MOSFET or IGBT, or between the p-doped channel region and an n-doped drift region of a JFET, or between the p-doped anode region and an n-doped drift region of a diode or thyristor. The body region or anode region may be formed by one or a plurality of body or anode sub-regions. The sub-regions may differ from one another with respect to at least one of dopant species, doping concentration profile, vertical extension. The sub-regions may overlap one another and form a continuous body or anode region, for example. For example, the body or anode region may be formed by an ion implantation process with subsequent drive-in steps. Body or anode sub-regions may be formed by a plurality of ion implantation processes with subsequent drive-in steps having different ion implantation energies and/or ion implantation doses. For example, the body or anode region may adjoin the first load electrode at the first surface.

The first load electrode may be a source contact of a MOSFET or JFET, or an anode contact of a diode or thyristor, or an emitter contact of an IGBT, over the first surface. The first load electrode may be part of a wiring area over the semiconductor body. The wiring area may include one or more than one, such as, for example, two, three, four or even more wiring levels. Each wiring level may be formed by a single one or a stack of conductive layers, for example a doped semiconductor material (e.g., a degenerate doped semiconductor material) such as doped polycrystalline silicon, metal or metal compound, for example. Each wiring level may also include a combination of these materials, such as, for example, a liner or adhesion material and an electrode material. Exemplary contact or electrode materials include one or more of titanium nitride (TiN) and tungsten (W), aluminum (Al), copper (Cu), alloys of aluminum or copper, for example AlSi, AlCu or AlSiCu, nickel (Ni), NiSi, titanium (Ti), tungsten (W), tantalum (Ta), silver (Ag), gold (Au), platinum (Pt), palladium (Pd), for example. The wiring levels may be lithographically patterned, for example. Between stacked wiring levels, an interlayer dielectric structure may be arranged. Contact plug(s) or contact line(s) may be formed in openings in the interlayer dielectric structure to electrically connect parts, such as, for example, metal lines or contact areas, of different wiring levels to one another. The first load electrode may be formed by one or more elements of the wiring area over the first surface. Likewise, the second load electrode may be a drain contact of a MOSFET or a JFET, or a cathode contact of a diode or thyristor, or a collector contact of an IGBT, and may be formed by one or more elements of the wiring area over the second surface. A part of the second load electrode may be a conductive filling material or a combination of conductive filling materials that at least partly fill the first trenches extending into the SiC semiconductor substrate from the second surface. The conductive filling may be electrically connected to the semiconductor body via the sidewalls of the first trenches. In addition, the conductive filling material may be electrically connected to the semiconductor body via a bottom side of the first trenches.

The blocking voltage of the vertical power semiconductor device may be adjusted by an impurity or doping concentration and/or a vertical extension of a drift region in the semiconductor body. The drift region may be part of the at least one SiC semiconductor layer and/or SiC substrate. A doping concentration of the drift region may gradually or in steps increase or decrease with increasing distance to the first surface at least in portions of its vertical extension. According to other examples, the impurity concentration in the drift region may be approximately uniform. A mean impurity concentration in the drift region may be between 5×10¹⁴ cm⁻³ and 1×10¹⁷ cm⁻³, for example in a range from 1×10¹⁵ cm⁻³ to 2×10¹⁶ cm⁻³. A vertical extent of the drift region may depend on voltage blocking requirements, such as, for example, a specified voltage class, of the device. When operating the vertical power semiconductor device in voltage blocking mode, a space charge region may vertically extend partly or totally through the drift region depending on the blocking voltage applied to the vertical power semiconductor device. When operating the vertical power semiconductor device at or close to the specified maximum blocking voltage, the space charge region may reach or penetrate into a buffer region that may be configured to prevent the space charge region from further reaching to the second load electrode at the second surface. The buffer region may have a higher doping concentration than the drift region. The vertical profile of doping concentration in the buffer region may enable an improvement of avalanche robustness and short circuit withstand capability. This may allow for improving reliability of the vertical power semiconductor device.

Provision of the plurality of first trenches at the second surface and filling the plurality of first trenches with part of the second load electrode may allow for increasing an electric contact area between semiconductor material and the second load electrode at the second surface. This may allow for reducing contribution of the contact resistance, such as, for example, rear side contact resistance, to the on-state resistance of the vertical power semiconductor device. Moreover, provision of the plurality of first trenches at the second surface and filling the plurality of first trenches with at least a part of the second load electrode may further allow for improving stress compensation, such as, for example, by reducing wafer bow or chip bow. Thereby, wafer handling in the fab and packaging may be facilitated.

For example, the plurality of first trenches may cover at least 30% of an active area of the vertical power semiconductor device at the second surface. In some examples, the plurality of first trenches covers more than 40%, or more than 50%, or even more than 60% % of an active area of the vertical power semiconductor device at the second surface.

For example, the plurality of first trenches may be V-shaped and may cover more than 30% of the active area of the vertical power semiconductor device at the second surface. The plurality of first V-shaped trenches may be formed by one or more wet etch processes, for example.

For example, the vertical power semiconductor device may further include a plurality of second trenches extending into the SiC semiconductor substrate from the first surface. The plurality of second trenches may be at least partly filled with an electrode material. The electrode material may be a conductive material of a gate electrode and/or field electrode. The plurality of second trenches may further include a dielectric, such as, for example, a gate dielectric and/or a field dielectric separating the electrode material from the semiconductor body, for example. For example, a first pitch of two adjacent trenches of the plurality of first trenches may range from 20% to 100% of a second pitch of two adjacent trenches of the plurality of second trenches.

Another example of the present disclosure relates to a further vertical power semiconductor device. Details with respect to structure, or function, or technical benefit of features described above likewise apply. The vertical power semiconductor device includes a SiC semiconductor body having a first surface and a second surface opposite to each other along a vertical direction. The SiC semiconductor body may include at least one SiC semiconductor layer on a SiC semiconductor substrate. The vertical power semiconductor device may include a pn junction in the at least one SiC semiconductor layer. The vertical power semiconductor device may further include a first load electrode over the first surface. The vertical power semiconductor device may further include a plurality of first trenches extending into the SiC semiconductor substrate from the second surface. The vertical power semiconductor device may further include a second load electrode over the second surface. The second load electrode may be electrically connected to the SiC semiconductor substrate via at least sidewalls, and such as, for example, a bottom, of the plurality of first trenches. A ratio between a depth of the plurality of first trenches and a thickness of the SiC semiconductor substrate ranges from 30% to 90%, or from 40% to 80%.

Provision of the plurality of first trenches at the second surface and filling the plurality of first trenches with least a part of the second load electrode may allow for increasing an electric contact area between semiconductor material and the second load electrode at the second surface. This may allow for reducing contribution of the contact resistance, such as, for example, rear side contact resistance, to the on-state resistance of the vertical power semiconductor device. Moreover, provision of the plurality of first trenches at the second surface and filling the plurality of first trenches with part of the second load electrode may further allow for improving stress compensation, such as, for example, by reducing wafer bow or chip bow. Thereby, wafer handling in the fab and packaging may be facilitated.

For example, the vertical power semiconductor device may further include a plurality of second trenches extending into the SiC semiconductor substrate from the first surface. The plurality of second trenches may be at least partly filled with an electrode material. The electrode material may be a conductive material of a gate electrode and/or field electrode. The plurality of second trenches may further include a dielectric, such as, for example, a gate dielectric and/or a field dielectric separating the electrode material from the semiconductor body, for example. For example, a first pitch of two adjacent trenches of the plurality of first trenches may be larger than a second pitch of two adjacent trenches of the plurality of second trenches.

For example, the vertical power semiconductor device may further include a graphene layer lining at least part of sidewalls of the plurality of first trenches. The graphene layer may be formed by a furnace process, for example. The graphene layer may be a mono-layer or may include several mono-layers, for example.

For example, the plurality of first trenches may be at least partly filled with an allotrope of carbon. Apart from graphene, other carbon allotropes may be used for improving electric and/or thermal conductivity of the vertical power semiconductor device.

For example, the plurality of first trenches may be at least partly filled with at least one of tungsten, silver, copper, titanium, titanium nitride, titanium carbide, tantalum, tantalum nitride molybdenum, molybdenum nitride

For example, the vertical power semiconductor device may further include an electrode layer directly adjoining the SiC semiconductor substrate at the second surface. The electrode layer may be a contact layer and may include at least one of Ti, Ta, W, Mo, Ni, NiAl, Al, TiN, TaN, MoN, WN, TiC.

For example, a ratio between a thickness of the at least one SiC semiconductor layer and the thickness of the SiC semiconductor substrate may range from 2% to infinity, infinity being 500% or larger.

For example, the vertical power semiconductor device may further include a doped region lining at least part of sidewalls, and such as, for example, also the bottom, of the plurality of first trenches. A doping concentration of the doped region may range from 10¹⁹ cm⁻³ to 5×10²¹ cm⁻³, for example.

For example, the plurality of first trenches may be arranged, in a top view, as a continuous grid, a two-dimensional array, or parallel stripes, or a cross. The plurality of first trenches may have different pitches along different lateral directions, for example. This may contribute to stress compensation that may be caused by an orientation of trenches at the first surface, for example.

Details with respect to structure, or function, or technical benefit of features described above with respect to a vertical power semiconductor device likewise apply to the exemplary methods described herein. Processing the semiconductor substrate and may comprise one or more optional additional features corresponding to one or more aspects mentioned in connection with the proposed concept or one or more examples described above or below.

An example of the present disclosure relates to a method for manufacturing a vertical power semiconductor device. The method includes providing a SiC semiconductor body having a first surface and a second surface opposite to each other along a vertical direction. The SiC semiconductor body may include at least one SiC semiconductor layer on a SiC semiconductor substrate. The method may further include forming a pn junction in the at least one SiC semiconductor layer. The method may further include forming a first load electrode over the first surface. The method may further include forming a plurality of first trenches extending into the SiC semiconductor substrate from the second surface. The method may further include forming a second load electrode over the second surface. The second load electrode may be electrically connected to the SiC semiconductor substrate via at least sidewalls, and such as, for example, the bottom, of the plurality of first trenches. A ratio between a minimum lateral extent of the plurality of first trenches at the second surface and a depth of the plurality of first trenches from the second surface may range from 0.5 to 5.

Another example of the present disclosure relates to a further method for manufacturing a vertical power semiconductor device. The method includes providing a SiC semiconductor body having a first surface and a second surface opposite to each other along a vertical direction. The SiC semiconductor body may include at least one SiC semiconductor layer on a SiC semiconductor substrate. The method may further include forming a pn junction in the at least one SiC semiconductor layer. The method may further include forming a first load electrode over the first surface. The method may further include forming a plurality of first trenches extending into the SiC semiconductor substrate from the second surface. The method may further include forming a second load electrode over the second surface. The second load electrode may be electrically connected to the SiC semiconductor substrate via at least sidewalls, and such as, for example, the bottom, of the plurality of first trenches. A ratio between a depth of the plurality of first trenches and a thickness of the SiC semiconductor substrate may range from 30% to 90%.

For example, the method may further include forming, by plasma doping (PLAD) a doped region lining at least part of sidewalls of the plurality of first trenches. A doping concentration of the doped region ranges from 10¹⁹ cm⁻³ to 5×10²¹ cm⁻³. For example, nitrogen and/or phosphorus may be used as dopants for PLAD. In addition, or as an alternative to PLAD, one or more ion implantations, such as, for example, tilted or non-tilted ion implantations or a combination thereof, may be used to form a highly doped semiconductor region lining at least part of sidewalls of the plurality of first trenches. This may allow for reducing an electric contact resistance between the semiconductor body and the second load electrode, for example.

For example, the method may further include electrically activating dopants in the doped region by laser annealing or by a high-temperature annealing step. Laser annealing parameters may be adjusted for non-melting laser annealing. The thermal budget for electrically activating the dopants by laser annealing may be supplemented by further thermal processes, such as, for example, rapid thermal processing (RTP), rapid thermal annealing (RTA), and/or furnace annealing.

For example, the method may include forming a graphene layer or a graphenic-like carbon layer lining at least part of sidewalls of the plurality of first trenches before forming the doped region by PLAD. The graphene layer may simplify ohmic contact formation between the semiconductor body and the second load electrode. For example, the graphene layer may allow for a reduced doping dose by PLAD for achieving a desired ohmic contact resistance. The graphene layer may be a mono-layer or may include several mono-layers, for example. Such layers are also very effective in preventing outdiffusion of the implanted ions.

For example, forming a graphene layer lining at least part of sidewalls of the plurality of first trenches may be carried out after forming the doped region by PLAD. This may allow for taking benefit of the thermal budget of graphene layer formation for electrically activating the dopants introduced into the semiconductor body by PLAD.

More details and aspects are mentioned in connection with the examples described above or below. Processing a SiC semiconductor wafer may comprise one or more optional additional features corresponding to one or more aspects mentioned in connection with the proposed concept or one or more examples described above or below.

The description and drawings merely illustrate the principles of the disclosure. Furthermore, all examples recited herein are principally intended expressly to be only for illustrative purposes to aid the reader in understanding the principles of the disclosure and the concepts contributed to furthering the art. All statements herein reciting principles, aspects, and examples of the disclosure, as well as specific examples thereof, are intended to encompass equivalents thereof.

It is to be understood that the disclosure of multiple acts, processes, operations, steps or functions disclosed in the specification or claims may not be construed as to be within the specific order, unless explicitly or implicitly stated otherwise, such as, for example, by expressions like “thereafter”, for instance for technical reasons. Therefore, the disclosure of multiple acts or functions will not limit these to a particular order unless such acts or functions are not interchangeable for technical reasons. Furthermore, in some examples a single act, function, process, operation or step may include or may be broken into multiple sub-acts, -functions, -processes, -operations or -steps, respectively. Such sub acts may be included and part of the disclosure of this single act unless explicitly excluded.

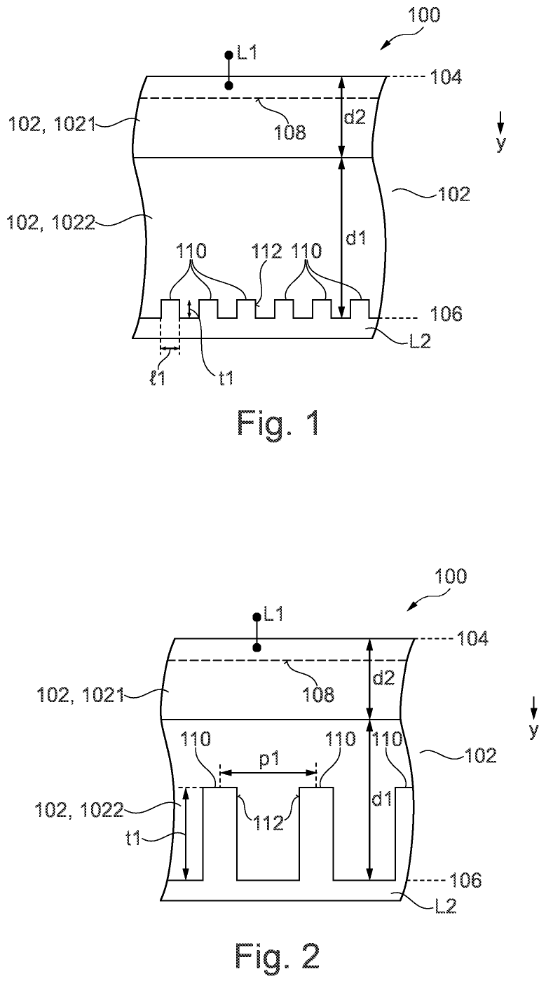

FIG. 1 schematically shows a partial cross-sectional view of an example of a vertical power semiconductor device 100.

The vertical power semiconductor device 100 includes a SiC semiconductor body 102 having a first surface 104 and a second surface 106 opposite to each other along a vertical direction y. The semiconductor body 102 includes a SiC semiconductor layer 1021 having a thickness d2 on a SiC semiconductor substrate 1022 having a thickness d1.

In the SiC semiconductor layer 1021, a pn junction 108 is schematically illustrated as a dashed line. The pn junction 108 in the SiC semiconductor layer may be a pn junction formed between a p-doped body region and an n-doped drift region of a MOSFET or IGBT, or between a p-doped anode region and an n-doped drift region of a diode or thyristor, for example. A first load electrode L1 over the first surface 104 may be electrically connected to the SiC semiconductor layer 1021.

A plurality of first trenches 110 extends into the SiC semiconductor substrate 1022 from the second surface 106. A second load electrode L2 may be arranged over the second surface 106. The second load electrode L2 may be electrically connected to the SiC semiconductor substrate 1022 via sidewalls 112 and a bottom side of the plurality of first trenches 110. A ratio between a minimum lateral extent l1 of the plurality of first trenches 110 at the second surface 106 and a depth t1 of the plurality of first trenches 110 from the second surface 106 may range from 0.5 to 5.

Another example of a vertical power semiconductor device 100 is schematically illustrated in the partial cross-sectional view of FIG. 2. While the examples of FIGS. 1, 2 are similar with respect to a variety of structural features, the examples of FIGS. 1, 2 may differ with respect to the design the plurality of first trenches 110. In the example illustrated in FIG. 2, a ratio between a depth t1 of the plurality of first trenches 110 and the thickness d1 of the SiC semiconductor substrate 1022 may range from 30% to 90%.

The examples illustrated in FIGS. 1 and 2 may be combined in a single semiconductor device.

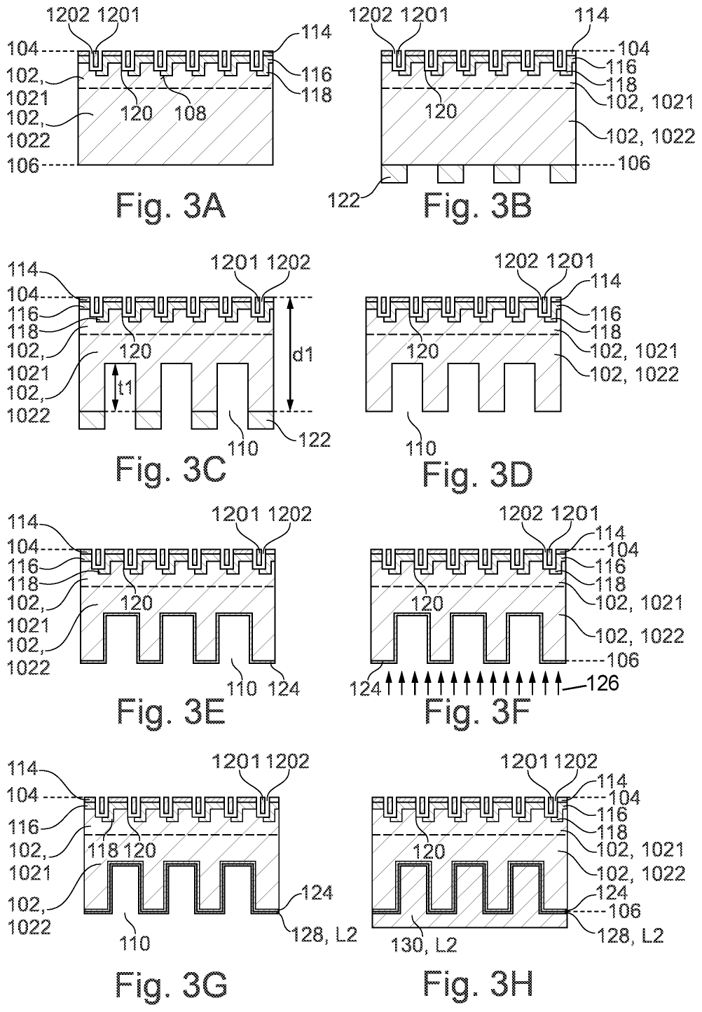

The schematic partial cross-sectional views of FIGS. 3A to 3H illustrate exemplary process features of a method of manufacturing a vertical power semiconductor device, such as, for example, the semiconductor device 100 illustrated in FIG. 2.

Referring to FIG. 3A, the semiconductor body 102 may be processed at the first surface 104. Processing the semiconductor body 102 at the first surface 104 includes forming semiconductor device elements in the semiconductor body. For example, processing the semiconductor body 104 at the first surface may include at least one doping process for forming doped regions in the semiconductor body 102. The at least one doping process may include an ion implantation or PLAD process followed by a thermal activation of dopants, or a diffusion process introducing the dopants into the semiconductor from a dopant source (e.g. solid or gaseous diffusion source). The exemplary doping processes may be combined in any way and may be repeated in any way, such as, for example, depending on a desired number and profile of the doped regions that are to be formed in the semiconductor body at the first surface. Exemplary doped regions are source region(s) 114 and drain region(s), or emitter and collector regions, body region(s) 116, body contact region(s), current spread region(s), shielding region(s) 118 configured to shield a gate dielectric from high electric fields, field stop region(s). Forming semiconductor device elements in the semiconductor body 102 by processing the semiconductor body 102 at the first surface 104 may also include trench etch processes. The trench etch processes may be used to form a plurality of second trenches 120 extending into the SiC semiconductor substrate 1022 from the first surface 104. The plurality of second trenches 120 may be or may include gate electrode trenches, multi-electrode trenches (e.g. combining gate and field electrodes in one trench), trenches for edge termination structures, contact trenches for providing an electric contact to doped regions in the semiconductor body 102. Forming semiconductor device elements in the semiconductor body 102 by processing the semiconductor body 102 at the first surface 104 may also include forming insulating layer(s), conductive layer(s), or any combination thereof, in the trenches. Exemplary insulating or conductive layers include, inter alia, gate electrode(s) 1201 or field electrodes by doped semiconductor layers (e.g. doped polycrystalline silicon, or metal, or metal alloy), oxide layers (e.g. silicate glass, deposited SiO₂, thermal SiO₂), nitride layers (e.g., Si₃N₄), high-k dielectric layers, low-k dielectric layers, dielectric spacers, or any combination thereof. One or more of the insulating layers may act as a gate dielectric 1202, for example.

After processing the semiconductor body 102 at the first surface 104, the semiconductor substrate may be reduced in thickness by a mechanical or chemical thinning process, or a combination thereof.

Processing the semiconductor body 102 at the first surface 104 may further include (not illustrated in FIG. 3A) forming a wiring area over the first surface 104 of the semiconductor body 102. The wiring area includes the first load electrode as a part thereof. The wiring area including the first load electrode may be arranged over an active area of the semiconductor body 102. The active area may be an area where the device elements in the semiconductor body 102, such as, for example, a transistor, diode, or thyristor cell array of the vertical power semiconductor device 100 (e.g. a power IGBT, a power MOSFET, a power JFET, a power thyristor, or a power diode), are electrically connected to the wiring area via the first surface 104. Apart forming the active area, processing the semiconductor body 102 at the first surface 104 may also include forming an edge termination area that at least partly surrounds the active area. The edge termination area may include a termination structure. The wiring area may laterally adjoin to a passivation area that may be arranged over the edge termination area of the vertical power semiconductor device 100, for example.

Referring to FIG. 3B, an etch mask 122, such as, for example, hard mask or resist mask, may be formed on the second surface 106 of the semiconductor body 102. The etch mask 122 may be patterned by a photolithographic process.

Referring to FIG. 3C, a plurality of first trenches 110 may be formed by one or more etch processes. The plurality of first trenches 110 extends into the SiC semiconductor substrate 1022 from the second surface 106. For example, a ratio between a depth t1 of the plurality of first trenches 110 and a thickness d1 of the SiC semiconductor substrate 1022 may range from 30% to 90%.

Referring to FIG. 3D, the etch mask 122 may be removed and a surface cleaning process may be carried out at the second surface 106.

Referring to FIG. 3E, dopants are introduced into a surface area of the semiconductor body 102 at the second surface 106 for forming a highly doped contact region 124. The highly doped contact region 124 may allow for a reduction of a contact resistance between the semiconductor body 102 and a load electrode at the second surface. The dopants, such as, for example, nitrogen and/or aluminum, may be introduced by PLAD and/or ion implantation, for example.

Referring to FIG. 3F, the dopants are electrically activated by a laser anneal process (schematically illustrated by arrows 126) and/or by any other suitable thermal treatment process, such as, for example, RTP, RTC and/or furnace annealing. Before or after forming the highly doped contact region 124, a graphene layer may be formed. The graphene layer may line sidewalls and a bottom side of the plurality of first trenches 110, for example.

Referring to FIG. 3G, a contact metal layer 128 as part of the second load electrode L2 may be formed in the plurality of first trenches 110 and on the second surface 106 of the semiconductor body 102.

Referring to FIG. 3H, an electrode material 130 as part of the second load electrode L2 may be filled in the plurality of first trenches 110 and over the second surface 106 of the semiconductor body 102. For example, the electrode material 130 may be or may include a power metal, such as, for example, Cu, and/or AlCu.

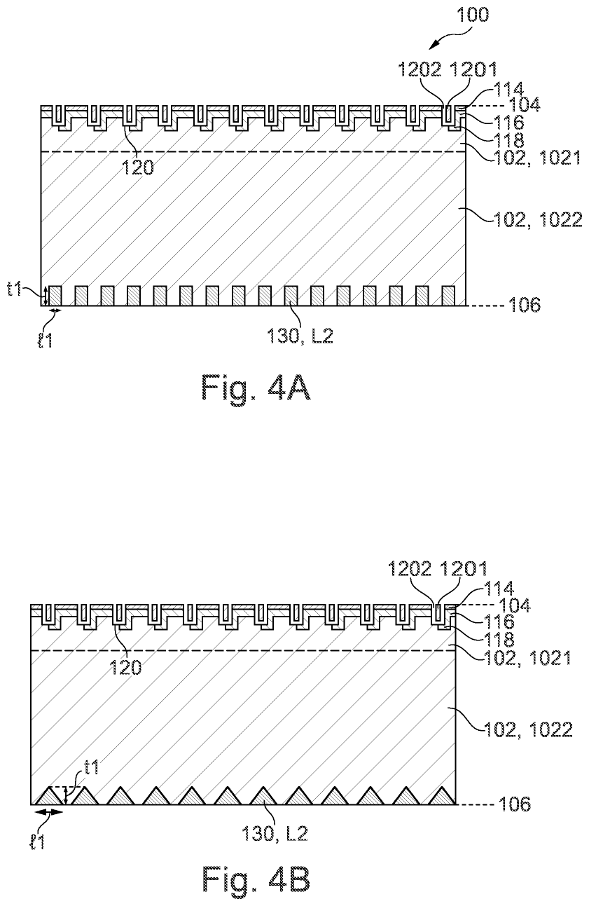

Processing as illustrated in the schematic partial cross-sectional views of FIGS. 3A to 3H described above may be likewise applied for manufacturing the vertical power semiconductor device illustrated in FIG. 1. This may result in a vertical power semiconductor device 100 as illustrated in the schematic partial cross-sectional views of FIGS. 4A, 4B. When forming the plurality of first trenches 110, a ratio between a minimum lateral extent l1 of the plurality of first trenches at the second surface 106 and a depth t1 of the plurality of first trenches 110 from the second surface 106 may be adjusted to range from 0.5 to 5, for example. As is illustrated in FIG. 4B, the plurality of first trenches 110 may be formed as V-shaped trenches.

The description and drawings merely illustrate the principles of the disclosure. Furthermore, all examples recited herein are principally intended expressly to be only for illustrative purposes to aid the reader in understanding the principles of the disclosure and the concepts contributed to furthering the art. All statements herein reciting principles, aspects, and examples of the disclosure, as well as specific examples thereof, are intended to encompass equivalents thereof.

The aspects and features mentioned and described together with one or more of the previously detailed examples and figures, may as well be combined with one or more of the other examples in order to replace a like feature of the other example or in order to additionally introduce the feature to the other example.

1. A vertical power semiconductor device, comprising:
a silicon carbide (SiC) semiconductor body having a first surface and a second surface opposite to each other along a vertical direction, wherein the SiC semiconductor body comprises at least one SiC semiconductor layer on a SiC semiconductor substrate;
a pn junction in the at least one SiC semiconductor layer;
a first load electrode over the first surface;
a plurality of first trenches extending into the SiC semiconductor substrate from the second surface; and
a second load electrode over the second surface, the second load electrode being electrically connected to the SiC semiconductor substrate via one or more sidewalls of the plurality of first trenches;
wherein a ratio between a minimum lateral extent of the plurality of first trenches at the second surface and a depth of the plurality of first trenches from the second surface ranges from 0.5 to 5.

2. The vertical power semiconductor device of claim 1, wherein the plurality of first trenches cover at least 30% of an active area of the vertical power semiconductor device at the second surface.

3. The vertical power semiconductor device of claim 1, wherein the plurality of first trenches is V-shaped and cover more than 30% of an active area of the vertical power semiconductor device at the second surface.

4. The vertical power semiconductor device of claim 1, further comprising a plurality of second trenches extending into the SiC semiconductor substrate from the first surface, wherein the plurality of second trenches is at least partly filled with an electrode material.

5. A vertical power semiconductor device, comprising:
a silicon carbide (SiC) semiconductor body having a first surface and a second surface opposite to each other along a vertical direction, wherein the SiC semiconductor body comprises at least one SiC semiconductor layer on a SiC semiconductor substrate;
a pn junction in the at least one SiC semiconductor layer;
a first load electrode over the first surface;
a plurality of first trenches extending into the SiC semiconductor substrate from the second surface; and
a second load electrode over the second surface, the second load electrode being electrically connected to the SiC semiconductor substrate via one or more sidewalls of the plurality of first trenches;
wherein a ratio between a depth of the plurality of first trenches and a thickness of the SiC semiconductor substrate ranges from 30% to 90%.

6. The vertical power semiconductor device of claim 5, further comprising a plurality of second trenches extending into the SiC semiconductor substrate from the first surface, wherein the plurality of second trenches is at least partly filled with an electrode material.

7. The vertical power semiconductor device of claim 5, further comprising a graphene layer lining at least part of one or more sidewalls of the plurality of first trenches.

8. The vertical power semiconductor device of claim 5, wherein the plurality of first trenches is at least partly filled with an allotrope of carbon.

9. The vertical power semiconductor device of claim 5, wherein the plurality of first trenches is at least partly filled with at least one of tungsten, silver, copper, titanium, titanium nitride, titanium carbide, tantalum, tantalum nitride molybdenum, or molybdenum nitride

10. The vertical power semiconductor device of claim 5, further comprising an electrode layer directly adjoining the SiC semiconductor substrate at the second surface, wherein the electrode layer comprises at least one of Ti, Ta, W, Mo, Ni, NiAl, Al, TiN, TaN, MoN, WN, or TiC.

11. The vertical power semiconductor device of claim 5, wherein a ratio between a thickness of the at least one SiC semiconductor layer and the thickness of the SiC semiconductor substrate ranges from 2% to infinity.

12. The vertical power semiconductor device of claim 5, further comprising a doped region lining at least part of one or more sidewalls of the plurality of first trenches, wherein a doping concentration of the doped region ranges from 10¹⁹ cm⁻³ to 5×10²¹ cm⁻³.

13. The vertical power semiconductor device of claim 5, wherein the plurality of first trenches is arranged, in a top view, as at least one of a continuous grid, a two-dimensional array, or parallel stripes.

14. A method for manufacturing a vertical power semiconductor device, the method comprising:
providing a silicon carbide (SiC) semiconductor body having a first surface and a second surface opposite to each other along a vertical direction, wherein the SiC semiconductor body comprises at least one SiC semiconductor layer on a SiC semiconductor substrate;
forming a pn junction in the at least one SiC semiconductor layer;
forming a first load electrode over the first surface;
forming a plurality of first trenches extending into the SiC semiconductor substrate from the second surface; and
forming a second load electrode over the second surface, the second load electrode being electrically connected to the SiC semiconductor substrate via one or more sidewalls of the plurality of first trenches;
wherein a ratio between a minimum lateral extent of the plurality of first trenches at the second surface and a depth of the plurality of first trenches from the second surface ranges from 0.5 to 5.

15. The method of claim 14, further comprising forming, by plasma doping (PLAD) a doped region lining at least part of one or more sidewalls of the plurality of first trenches.

16. A method for manufacturing a vertical power semiconductor device, the method comprising:
providing a silicon carbide (SiC) semiconductor body having a first surface and a second surface opposite to each other along a vertical direction, wherein the SiC semiconductor body comprises at least one SiC semiconductor layer on a SiC semiconductor substrate;
forming a pn junction in the at least one SiC semiconductor layer;
forming a first load electrode over the first surface;
forming a plurality of first trenches extending into the SiC semiconductor substrate from the second surface; and
forming a second load electrode over the second surface, the second load electrode being electrically connected to the SiC semiconductor substrate via one or more sidewalls of the plurality of first trenches;
wherein a ratio between a depth of the plurality of first trenches and a thickness of the SiC semiconductor substrate ranges from 30% to 90%.

17. The method of claim 16, further comprising forming, by plasma doping (PLAD) a doped region lining at least part of one or more sidewalls of the plurality of first trenches.

18. The method of claim 17, further comprising electrically activating dopants in the doped region by at least one of laser annealing or a high-temperature annealing step.

19. The method of claim 17, further comprising forming a graphene layer lining at least part of one or more sidewalls of the plurality of first trenches before forming the doped region by PLAD.

20. The method of claim 17, further comprising forming a graphene layer lining at least part of one or more sidewalls of the plurality of first trenches after forming the doped region by PLAD.
